(19) United States
(12) Patent Application Publication
(10) Pub. No.: US 2019/0069411 A1
(43) Pub. Date: Feb. 28, 2019

(54) ELECTRONIC COMPONENT AND BOARD HAVING THE SAME

(71) Applicant: SAMSUNG ELECTRO-MECHANICS CO., LTD., Suwon-Si (KR)

(72) Inventors: Heung Kil PARK, Suwon-Si (KR); Gu Won JI, Suwon-Si (KR); Se Hun PARK, Suwon-Si (KR)

(21) Appl. No.: 15/987,407

(22) Filed: May 23, 2018

(30) Foreign Application Priority Data
Aug. 25, 2017 (KR) 10-2017-0107698

(51) Int. Cl. H05K 1/18; H05K 1/11; H01G 4/30; H01G 4/008; H01G 4/224

(52) U.S. Cl. CPC H05K 1/181; H05K 1/111; H01G 4/30; H01G 4/248; H01G 4/224; H05K 2201/10015; H01G 4/008

(57) ABSTRACT

An electronic component includes: a multilayer capacitor having both ends on which external electrodes are disposed; connection terminals including vertical portions, lower horizontal portions having cut portions, respectively, and upper horizontal portions, respectively, lower surfaces of the upper horizontal portions being connected to the external electrodes; and a tantalum capacitor disposed on upper surfaces of the upper horizontal portions to be electrically connected thereto.

### CROSS-REFERENCE TO RELATED APPLICATION(S)

This application claims benefit of priority to Korean Patent Application No. 10-2017-0107698 filed on Aug. 25, 2017 in the Korean Intellectual Property Office, the disclosure of which is incorporated herein by reference in its entirety.

### TECHNICAL FIELD

The present disclosure relates to an electronic component and a board having the same.

### BACKGROUND

A multilayer capacitor, a multilayer electronic component, may be formed of a dielectric material, and since the dielectric material has piezoelectric properties, displacement may occur due to synchronization with an applied voltage.

When a period of the applied voltage is within an audio frequency band, the displacement may become vibrations to thereby be transferred to a board through solders, and vibrations of the board may be experienced as sound. This sound is referred to as acoustic noise.

In a case in which a device is operated in a silent environment, a user may experience the acoustic noise as abnormal sound and as a fault of the device. In addition, in a device having an audio circuit, the acoustic noise may be overlapped with audio output, such that quality of the device may be deteriorated.

Further, separately from acoustic noise recognized by human ears, when piezoelectric vibrations of the multilayer capacitor are generated in a high frequency region of 20 kHz or more, piezoelectric vibrations may cause malfunctioning of various sensors used in information technology (IT) and industrial/electronic fields.

Meanwhile, external electrodes of the multilayer capacitor and a circuit board may be connected to each other by solders, and the solders may be formed to be inclined along surfaces of the external electrodes from both side surfaces or both end surfaces of a capacitor body at a predetermined height.

In this case, as a height and a volume of the solders are increased, vibrations of the multilayer capacitor may be more easily transferred to the circuit board, and thus, a level of the acoustic noise generated therein may also be increased.

### SUMMARY

An aspect of the present disclosure may provide an electronic component capable of decreasing acoustic noise and high-frequency vibrations of 20 kHz or more while improving electrical properties and reliability, and a board having the same.

According to an aspect of the present disclosure, an electronic component may include: a capacitor body including a plurality of dielectric layers and a plurality of first and second internal electrodes alternately disposed with respective dielectric layers interposed therebetween and having first and second surfaces opposing each other, third and fourth surfaces connected to the first and second surfaces and opposing each other, and fifth and sixth surfaces connected to the first and second surfaces and the third and fourth surfaces and opposing each other, one ends of the first and second internal electrodes being exposed to the third and fourth surfaces of the capacitor body; first and second external electrodes disposed on the third and fourth surfaces of the capacitor body, respectively; and first and second connection terminals connected to the first and second external electrodes, respectively. The first connection terminal may include: a first vertical portion disposed to face the first external electrode; a first lower horizontal portion extending from a lower end of the first vertical portion in a direction toward the fourth surface of the capacitor body; a first upper horizontal portion extending from an upper end of the first vertical portion in the direction toward the fourth surface of the capacitor body; and a first cut portion formed in a portion connecting the first vertical portion and the first lower horizontal portion. The second connection terminal may include: a second vertical portion disposed to face the second external electrode; a second lower horizontal portion extending from a lower end of the second vertical portion in a direction toward the third surface of the capacitor body; a second upper horizontal portion extending from an upper end of the second vertical portion in the direction toward the third surface of the capacitor body; and a second cut portion formed in a portion connecting the second vertical portion and the second lower horizontal portion. The electronic component may further include a tantalum capacitor having an anode and a cathode connected to the second and first upper horizontal portions, respectively.

The first and second upper horizontal portions may be adhered to the first and second external electrodes, respectively, the first vertical portion and the first lower horizontal portion may be disposed to be spaced apart from the first external electrode, and the second vertical portion and the second lower horizontal portion may be disposed to be spaced apart from the second external electrode.

The first and second lower horizontal portions may be mounting portions.

The first cut portion may include: a first stress suppression portion formed in the lower end of the first vertical portion; and a first solder pocket communicating with the first stress suppression portion and formed in one end of the first lower horizontal portion, and the second cut portion may include: a second stress suppression portion formed in the lower end of the second vertical portion; and a second solder pocket communicating with the second stress suppression portion and formed in one end of the second lower horizontal portion.

The first cut portion may be positioned in a center of the first connection terminal in a direction in which the fifth and sixth surfaces of the capacitor body are connected to each other, and the second cut portion may be positioned in a center of the second connection terminal in the direction in which the fifth and sixth surfaces of the capacitor body are connected to each other.

The electronic component may further include conductive adhesive layers disposed between the first external electrode and the first upper horizontal portion and between the second external electrode and the second upper horizontal portion, respectively.

The first and second external electrodes may respectively include first and second body portions disposed on the third and fourth surfaces of the capacitor body, respectively; and first and second band portions extending from the first and second body portions to portions of the second surface of the capacitor body, respectively, the first and second vertical portions may be disposed to be spaced apart from the first and second body portions, respectively, and the first and second upper horizontal portions may be connected to the first and second band portions, respectively.

The first connection terminal may further include a third cut portion formed in a portion connecting the first vertical portion and the first upper horizontal portion, and the second connection terminal may further include a fourth cut portion formed in a portion connecting the second vertical portion and the second upper horizontal portion.

The third cut portion may include: a third stress suppression portion formed in the upper end of the first vertical portion; and a third solder pocket communicating with the third stress suppression portion and formed in one end of the first upper horizontal portion, and the fourth cut portion may include: a fourth stress suppression portion formed in the upper end of the second vertical portion; and a fourth solder pocket communicating with the fourth stress suppression portion and formed in one end of the second upper horizontal portion.

The third cut portion may be positioned in a center of the first connection terminal in a direction in which the fifth and sixth surfaces of the capacitor body are connected to each other, and the fourth cut portion may be positioned in a center of the second connection terminal in the direction in which the fifth and sixth surfaces of the capacitor body are connected to each other.

The electronic component may further include a protection part formed of an insulator, and formed to cover the capacitor body, the first and second external electrodes, and at least portions of upper portions of first and second connection terminals in a state in which the first and second cut portions are exposed, and formed to expose the first and second upper horizontal portions of the first and second connection terminals.

The tantalum capacitor may include: a tantalum body; a tantalum wire exposed to one surface of the tantalum body; an anode terminal connected to the tantalum wire; a cathode terminal on which the tantalum body is mounted; and a cover part covering the tantalum body and the tantalum wire and exposing a lower surface of the anode terminal and a lower surface of the cathode terminal.

According to another aspect of the present disclosure, an electronic component may include: a multilayer capacitor having both ends on which external electrodes are disposed; connection terminals including vertical portions, lower horizontal portions having cut portions, respectively, and upper horizontal portions, respectively, lower surfaces of the upper horizontal portions being connected to the external electrodes; and a tantalum capacitor disposed on upper surfaces of the upper horizontal portions to be electrically connected thereto.

According to another aspect of the present disclosure, a board having an electronic component, may include: a circuit board having one surface on which first and second electrode pads are formed; and the electronic component described above, mounted on the first and second electrode pads. The first and second lower horizontal portions of the first and second connection terminals may be connected to the first and second electrode pads, respectively.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a perspective view illustrating an electronic component according to a first exemplary embodiment in the present disclosure;

FIG. 2 is a perspective view illustrating a multilayer capacitor and connection terminals of FIG. 1;

FIG. 3 is a cross-sectional view taken along line I-I′ of FIG. 2;

FIGS. 4A and 4B are plan views illustrating first and second internal electrodes of the multilayer capacitor of FIG. 2, respectively;

FIG. 5 is a transparent perspective view illustrating a tantalum capacitor of FIG. 1;

FIG. 6 is a cross-sectional view taken along line II-II′ of FIG. 5;

FIG. 7 is a perspective view illustrating an electronic component according to a second exemplary embodiment in the present disclosure;

FIG. 8 is a perspective view illustrating a multilayer capacitor and connection terminals of FIG. 7;

FIG. 9 is a transparent exploded perspective view illustrating an electronic component according to a third exemplary embodiment in the present disclosure; and

FIG. 10 is a front view schematically illustrating a board in which the electronic component according to the first exemplary embodiment in the present disclosure is mounted on a circuit board.

### DETAILED DESCRIPTION

Hereinafter, exemplary embodiments of the present disclosure will be described in detail with reference to the accompanying drawings.

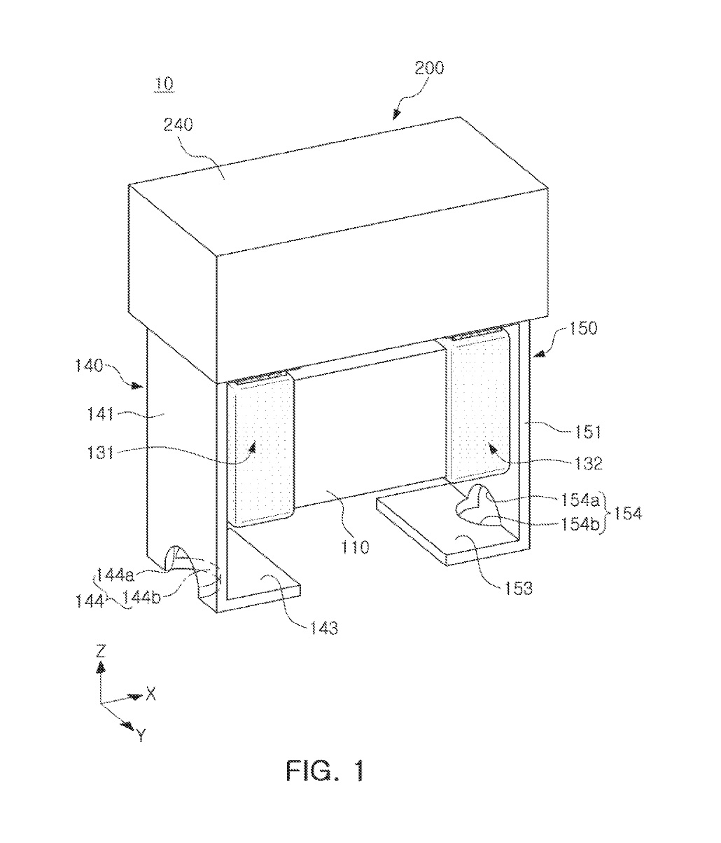

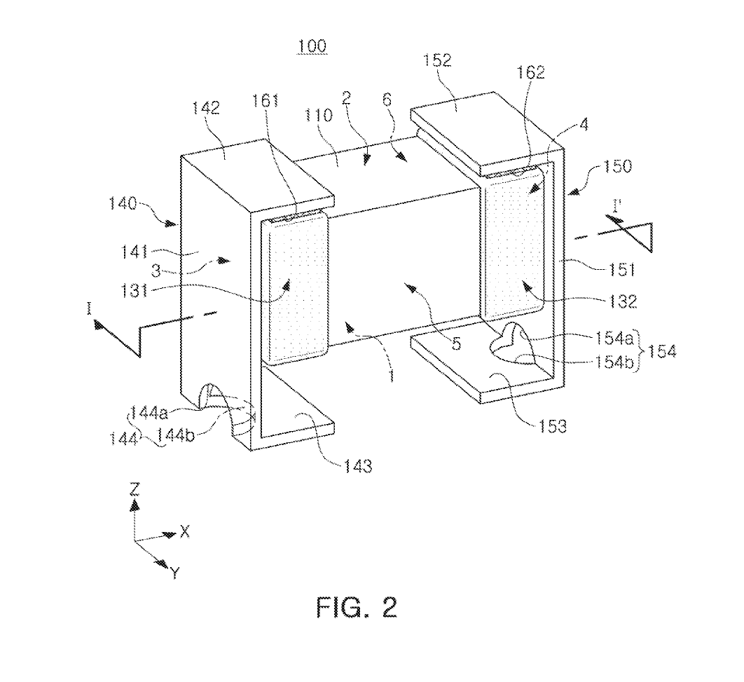

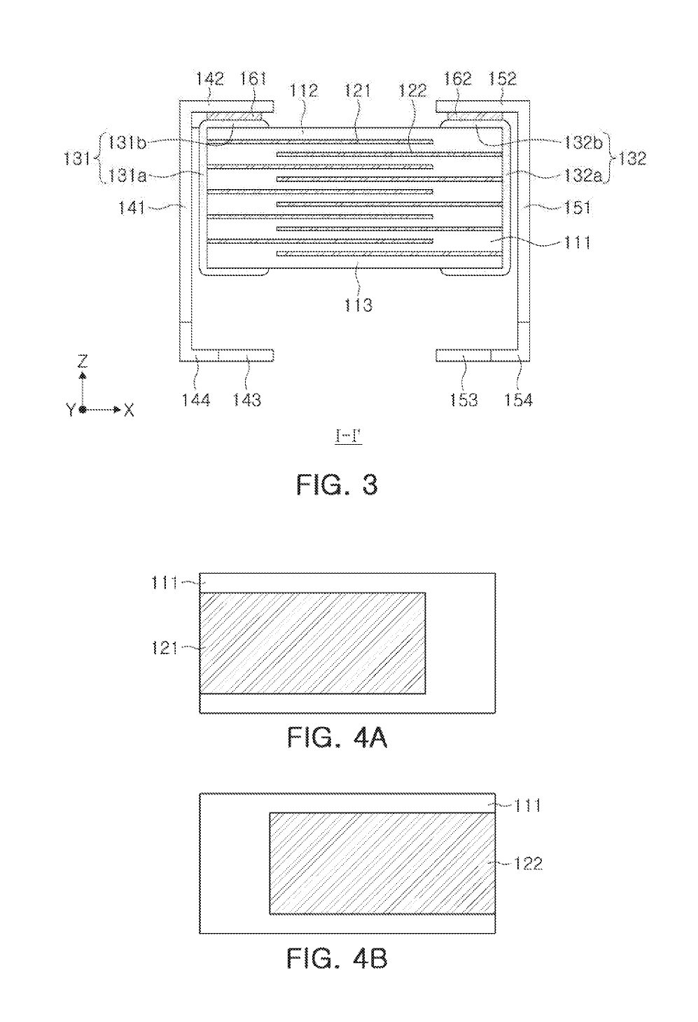

FIG. 1 is a perspective view illustrating an electronic component according to a first exemplary embodiment in the present disclosure, FIG. 2 is a perspective view illustrating a multilayer capacitor and connection terminals of FIG. 1, FIG. 3 is a cross-sectional view taken along line I-I′ of FIG. 2, and FIGS. 4A and 4B are plan views illustrating first and second internal electrodes of the multilayer capacitor of FIG. 2, respectively.

Referring to FIGS. 1 through 4B, an electronic component 10 according to the first exemplary embodiment in the present disclosure may include a multilayer capacitor 100, a tantalum capacitor 200, and first and second connection terminals 140 and 150. Further, the multilayer capacitor 100 according to the present exemplary embodiment may include a capacitor body 110 and first and second external electrodes 131 and 132.

Hereinafter, directions of a capacitor body 110 will be defined in order to clearly describe exemplary embodiments in the present disclosure. X, Y, and Z illustrated in the accompanying drawings refer to a length direction, a width direction, and a thickness direction of the capacitor body 110, respectively. Here, in the present exemplary embodiment, the thickness direction may be the same as a stacking direction in which the dielectric layers 111 are stacked.

The capacitor body 110 according to the present exemplary embodiment may be formed by stacking a plurality of dielectric layers 111 in the Z direction and sintering the stacked dielectric layers, and include the plurality of dielectric layers 111 and a plurality of first and second internal electrodes 121 and 122 alternately disposed with respective dielectric layers 111 interposed therebetween in the Z direction.

In addition, if necessary, covers 112 and 113 maybe formed at a predetermined thickness on both sides of the capacitor body in the Z direction, respectively. Here, respective adjacent dielectric layers 111 of the capacitor body 110 may be integrated with each other so that boundaries therebetween are not readily apparent.

The capacitor body 110 may have an approximately hexahedral shape. However, a shape of the capacitor body 110 is not limited thereto.

In the present exemplary embodiment, for convenience of explanation, both surfaces of the capacitor body 110 opposing each other in the Z direction may be defined first and second surfaces 1 and 2, both surfaces of the capacitor body 110 connected to the first and second surfaces 1 and 2 and opposing each other in the X direction may be defined as third and fourth surfaces 3 and 4, and both surfaces of the capacitor body 110 connected to the first and second surfaces 1 and 2 and the third and fourth surfaces 3 and 4 and opposing each other in the Y direction may be defined as fifth and sixth surfaces 5 and 6.

The dielectric layer 111 may contain a ceramic material having high permittivity, for example, a barium titanate (BaTiO₃) based ceramic powder, or the like. However, the material of the dielectric layer is not limited thereto.

An example of the barium titanate (BaTiO₃) based ceramic powder may include (Ba₁₋ₓCaₓ)TiO₃, Ba(Ti_{1-y}Ca_{y})O₃, (Ba₁₋ₓCaₓ) (Ti_{1-y}Zr_{y})O₃, Ba(Ti_{1-y}Zr_{y})O₃, and the like, in which Ca, Zr, or the like, is partially dissolved in BaTiO₃. However, an example of the barium titanate (BaTiO₃) based ceramic powder is not limited thereto.

In addition, the dielectric layer 111 may further contain a ceramic additive, an organic solvent, a plasticizer, a binder, a dispersant, and the like, in addition to the ceramic powder. As the ceramic additive, for example, a transition metal oxide or carbide, a rare earth element, magnesium (Mg), aluminum (Al), or the like, may be used.

The first and second internal electrodes 121 and 122, which are electrodes applied with voltages having different polarities, may be alternately disposed to face each other in the Z direction with respective dielectric layers 111 interposed therebetween, and one ends of the first and second internal electrodes 121 and 122 may be exposed to the third and fourth surfaces 3 and 4 of the capacitor body 110, respectively.

Here, the first and second internal electrodes 121 and 122 may be electrically insulated from each other by the dielectric layer 111 disposed therebetween.

End portions of the first and second internal electrodes 121 and 122 alternately exposed to the third and fourth surfaces 3 and 4 of the capacitor body 110 as described above may be electrically connected to first and second external electrodes 131 and 132 disposed on the third and fourth surfaces 3 and 4 of the capacitor body 110 to be described below.

Here, the first and second internal electrodes 121 and 122 may be formed of a conductive metal, for example, a material such as nickel (Ni), a nickel (Ni) alloy, or the like. However, materials of the first and second internal electrodes 121 and 122 are not limited thereto.

According to the configuration as described above, when predetermined voltages are applied to the first and second external electrodes 131 and 132, electric charges may be accumulated between the first and second internal electrodes 121 and 122 facing each other. Here, capacitance of the multilayer capacitor 100 may be in proportion to an overlapping area between the first and second internal electrodes 121 and 122 overlapping each other in the Z direction.

The first and second external electrodes 131 and 132 may be provided with voltages having different polarities, respectively, and electrically connected to the exposed end portions of the first and second internal electrodes 121 and 122, respectively.

If necessary, plating layers may be further formed on surfaces of the first and second external electrodes 131 and 132 as described above. For example, the first and second external electrodes 131 and 132 may respectively include first and second conductive layers connected to the first and second internal electrodes 121 and 122, respectively, first and second nickel (Ni) plating layers formed on the first and second conductive layers, respectively, and first and second tin (Sn) plating layers formed on the first and second nickel (Ni) plating layers, respectively.

The first external electrode 131 may include a first body portion 131a and a first band portion 131b.

The first body portion 131a may be a portion formed on the third surface 3 of the capacitor body 110 and connected to the first internal electrode 121, and the first band portion 131b may be a portion extending from the first body portion 131a to a portion of the second surface 2 of the capacitor body 110.

Here, in order to improve adhesive strength, or the like, the first band portion 131b may further extending to a portion of the first surface 1 of the capacitor body 110 and portions of the fifth and sixth surfaces 5 and 6 of the capacitor body 110.

The second external electrode 132 may include a second body portion 132a and a second band portion 132b.

The second body portion 132a may be a portion formed on the fourth surface 4 of the capacitor body 110 and connected to the second internal electrode 122, and the second band portion 132b may be a portion extending from the second body portion 132a to a portion of the second surface 2 of the capacitor body 110.

Here, in order to improve adhesive strength, or the like, the second band portion 132b may further extending to a portion of the first surface 2 of the capacitor body 110 and portions of the fifth and sixth surfaces 5 and 6 of the capacitor body 110.

The first connection terminal 140 may be connected to the first external electrode 131, be formed of a conductor, and include a first vertical portion 141, a first upper horizontal portion 142, and a first lower horizontal portion 143.

The first vertical portion 141 may be disposed to face the first body portion 131a of the first external electrode 131.

Here, the first vertical portion 141 may be formed to have a size and a shape enough to entirely cover the first body portion 131a of the first external electrode 131.

Further, the first vertical portion 141 may be disposed to be spaced apart from the first body portion 131a by a predetermined interval.

The first upper horizontal portion 142 may be a portion extending from an upper end of the first vertical portion 141 toward the fourth surface 4 of the capacitor body 110 in the X direction.

The first upper horizontal portion 142 may be adhered to the first external electrode 131 and serve to electrically connect the first connection terminal 140 and the first external electrode 131 to each other.

That is, the first band portion 131b of the first external electrode 131 may come in contact with a lower surface of the first upper horizontal portion 142.

The first lower horizontal portion 143 may be a portion extending from a lower end of the first vertical portion 141 toward the fourth surface 4 of the capacitor body 110 in the X direction.

Further, the first lower horizontal portion 143 may be disposed to be spaced apart from the first band portion 131b and the first surface 1 of the capacitor body 110 by a predetermined interval.

The first lower horizontal portion 143 as described above may be a mounting portion, and at the time of mounting the electronic component 10 on a circuit board, a lower surface of the first lower horizontal portion 143 may be a mounting surface.

In addition, a first cut portion 144 may be formed in a portion connecting the first vertical portion 141 and the first lower horizontal portion 143 to each other.

The first cut portion 144 may include a first stress suppression portion 144a formed on the lower end of the first vertical portion 141 and a first solder pocket 144b communicating with the first stress suppression portion 144a and formed in one end of the first lower horizontal portion 143.

Here, the first cut portion 144 may be positioned in the center of the first connection terminal 140 in the Y direction corresponding to a direction in which the fifth and sixth surfaces 5 and 6 of the capacitor body 110 are connected to each other.

The second connection terminal 150 may be connected to the second external electrode 132, be formed of a conductor, and include a second vertical portion 151, a second upper horizontal portion 152, and a second lower horizontal portion 153.

The second vertical portion 151 may be disposed to face the second body portion 132a of the second external electrode 132.

Here, the second vertical portion 151 may be formed to have a size and a shape enough to entirely cover the second body portion 132a of the second external electrode 132.

Further, the second vertical portion 151 may be disposed to be spaced apart from the second body portion 132a by a predetermined interval.

The second upper horizontal portion 152 may be a portion extending from an upper end of the second vertical portion 151 toward the third surface 3 of the capacitor body 110 in the X direction.

The second upper horizontal portion 152 may be adhered to the second external electrode 132 and serve to electrically connect the second connection terminal 150 and the second external electrode 131 to each other.

That is, the second band portion 132b of the second external electrode 132 may come in contact with a lower surface of the second upper horizontal portion 152.

The second lower horizontal portion 153 may be a portion extending from a lower end of the second vertical portion 151 toward the third surface 3 of the capacitor body 110 in the X direction.

Further, the second lower horizontal portion 153 may be disposed to be spaced apart from the second band portion 132b and the first surface 1 of the capacitor body 110 by a predetermined interval.

The second lower horizontal portion 153 as described above may be a mounting portion, and at the time of mounting the electronic component 10 on the circuit board, a lower surface of the second lower horizontal portion 153 may be a mounting surface.

In addition, a second cut portion 154 may be formed in a portion connecting the second vertical portion 151 and the second lower horizontal portion 153 to each other.

The second cut portion 154 may include a second stress suppression portion 154a formed on the lower end of the second vertical portion 151 and a second solder pocket 154b communicating with the second stress suppression portion 154a and formed in one end of the second lower horizontal portion 153.

Here, the second cut portion 154 may be positioned in the center of the second connection terminal 150 in the Y direction corresponding to the direction in which the fifth and sixth surfaces 5 and 6 of the capacitor body 110 are connected to each other.

The first and second stress suppression portions 144a and 154a may serve to disperse stress by piezoelectric vibration transferred from the capacitor body 110 to suppress the stress and decrease the transferring of the vibration, thereby decreasing acoustic noise.

Further, the first and second stress suppression portions 144a and 154a may decrease impact applied to the electronic component 10 by dispersing external impact or stress transferred from a set board to the capacitor body 110 at the time of mounting the electronic component 10 on a circuit board, thereby improving reliability of a product.

The first and second solder pockets 144b and 154b may efficiently block a path through which the piezoelectric vibration of the capacitor body 110 is transferred by limiting a height at which a solder fillet is formed at the time of mounting the electronic component 10 on a circuit board and forming solder, thereby decreasing acoustic noise.

In addition, conductive adhesive layers 161 and 162 may be disposed between the first and second band portions 131 and 132 of upper portions of the first and second external electrodes 131 and 132 and the lower surfaces of the first and second upper horizontal portions 142 and 152, respectively. The conductive adhesive layers 161 and 162 as described above may be formed of high-temperature solder, a conductive resin paste, or the like.

Further, surfaces of the first and second connection terminals 140 and 150 may be plated with a metal that is easy to solder. The metal may be, for example, nickel, tin, or the like, but is not limited thereto.

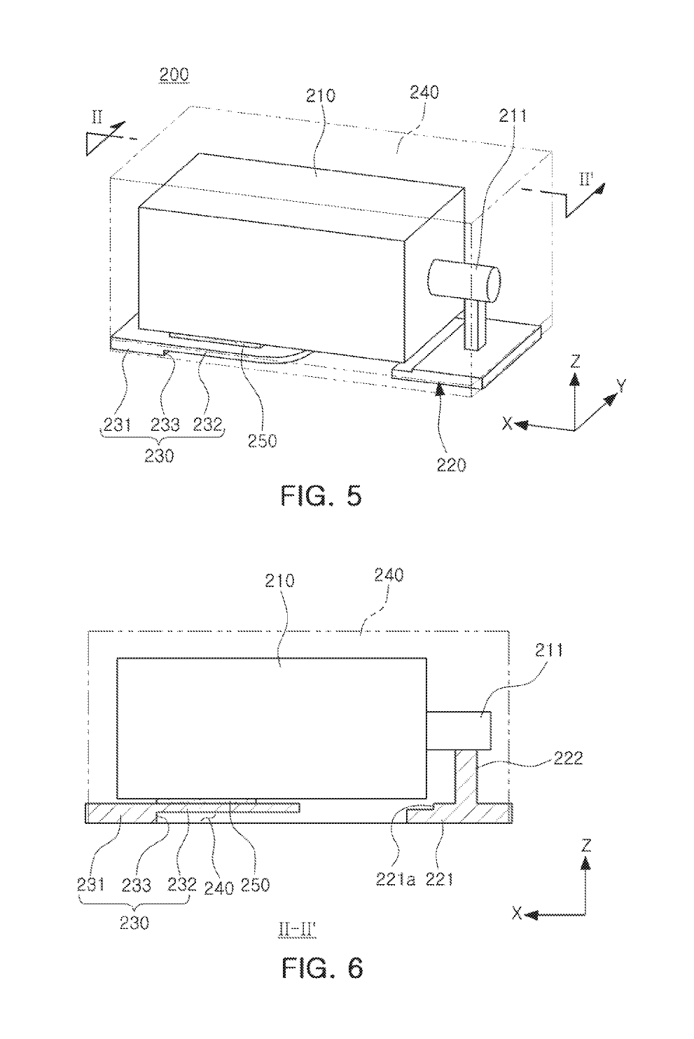

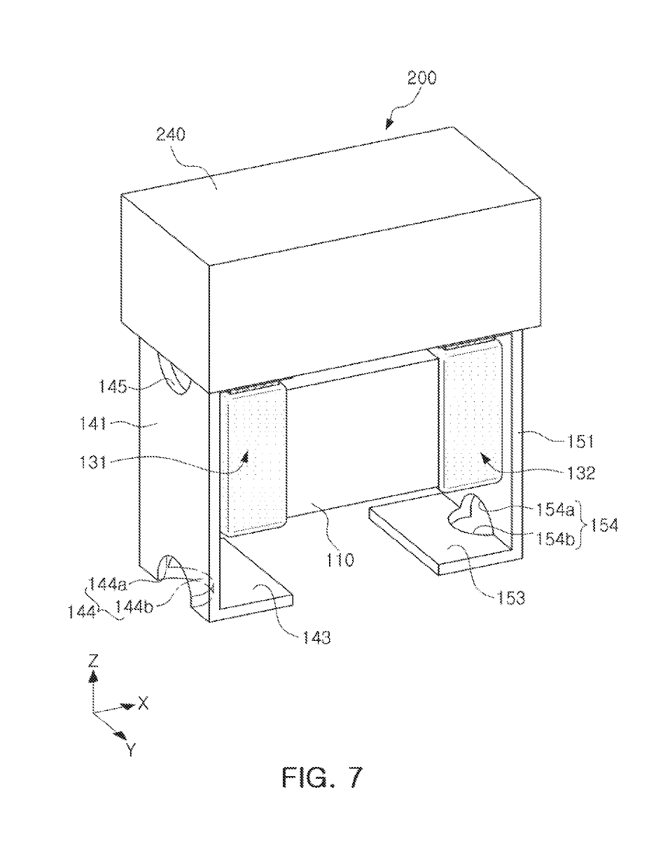

FIG. 5 is a transparent perspective view illustrating a tantalum capacitor of FIG. 1, and FIG. 6 is a cross-sectional view taken along line II-II′ of FIG. 5.

Referring to FIGS. 5 and 6, a tantalum capacitor 200 according to the present exemplary embodiment may include a tantalum body 210, a tantalum wire 211 exposed to one surface of the tantalum body 210, an anode terminal 220 connected to a tantalum wire 211, and a cathode terminal 230 on which the tantalum body 210 is mounted.

Further, the tantalum capacitor 200 according to the present exemplary embodiment may include a cover part 240 formed to cover the tantalum body 210 and the tantalum wire 211 and expose a lower surface of the anode terminal 220 and a lower surface of the cathode terminal 230.

The tantalum body 210 may contain a tantalum powder and serve as a cathode of the tantalum capacitor 200.

The tantalum wire 211 may serve as an anode of the tantalum capacitor 200. The tantalum wire 211 as described above may include an insertion region positioned in the tantalum body 210 and a non-insertion region extending from the insertion region so as to be exposed to one side surface of the tantalum body 210.

The anode terminal 220 may be formed of a conductive metal such as a nickel/iron alloy, or the like, and include an anode terminal portion 221 and a wire connection portion 222.

The anode terminal portion 221 may be exposed to a lower surface of the cover part 240, and disposed on the upper surface of the second upper horizontal portion 152 of the second connection terminal 150 to thereby be electrically connected to another electronic product.

Further, an upper surface of the anode terminal portion 221 may have a step 221a. Here, the step 221a may serve to prevent a short-circuit from occurring due to a contact between the tantalum body 210 and the anode terminal portion 221.

The wire connection portion 222 may be a portion protruding upwardly from a portion of the upper surface of the anode terminal portion 221, and upper end of the wire connection portion 222 may be electrically connected to the tantalum wire 211.

The cathode terminal 230 may be formed of a conductive metal such as a nickel/iron alloy, or the like.

Further, the cathode terminal 230 may be disposed to be in parallel with and be spaced apart from the anode terminal portion 221 of the anode terminal 220 in the X direction, and a lower surface thereof may be exposed to the lower surface of the cover part 240 to thereby be used as a connection terminal for electrical connection with another electronic product.

In addition, an upper surface of the cathode terminal 232 may be formed to be flat in order to secure an adhesive area with the tantalum body 210, and the tantalum body 210 may be mounted thereon and electrically connected thereto.

Further, the cathode terminal 230 may have a step 233 so that a portion of the cover part 240 may be formed on a portion of the lower surface thereof. In the present exemplary embodiment, the cathode terminal 230 may be divided into a cathode terminal portion 231 and a cathode mounting portion 232 on which the tantalum body 210 is mounted based on the step 233.

Meanwhile, in the cathode terminal 230, a conductive adhesive layer 250 may be formed between an upper surface of the cathode mounting portion 232 and a lower surface of the tantalum body 210 in order to improve adhesive strength of the cathode terminal 230.

The conductive adhesive layer 250 as described above may be formed, for example, by dispensing a predetermined amount of a conductive adhesive containing an epoxy based thermosetting resin and conductive metal powder or by point-dotting the conductive adhesive, but the conductive adhesive layer 250 is not limited thereto.

For example, high-melting point solder may be used in the conductive adhesive layer 250. In addition, as the conductive metal powder, copper (Cu) may be used, but the conductive metal powder is not limited thereto.

The cover part 240 may be formed by transfer-molding a resin such as epoxy molding compound (EMC), or the like, so as to enclose the tantalum body 210.

The cover part 240 as described above may serve to insulate the tantalum body 210 and the anode terminal 220 from each other in addition to serving to protect the tantalum wire 211 and the tantalum body 210.

In this case, the cover part 240 may be formed to expose the lower surface of the anode terminal portion 221 of the anode terminal 220 and the lower surface of the cathode terminal portion 231 of the cathode terminal 230.

Therefore, the lower surface of the anode terminal portion 221 may be disposed to be connected to the upper surface of the second upper horizontal portion 153 of the second connection terminal 150, and the lower surface of the cathode terminal portion 231 may be disposed to be connected to the upper surface of the first upper horizontal portion 142 of the first connection terminal 140.

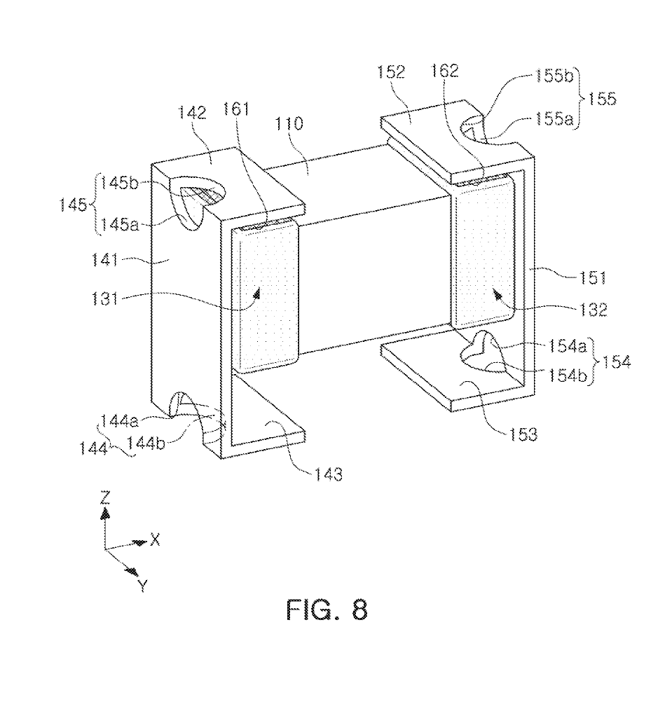

FIG. 7 is a perspective view illustrating an electronic component according to a second exemplary embodiment in the present disclosure, and FIG. 8 is a perspective view illustrating a multilayer capacitor and connection terminals of FIG. 7.

Since in the electronic component according to the second exemplary embodiment, structures of a capacitor body 110, first and second internal electrodes 121 and 122, and first and second external electrodes 131 and 132 are the same as those in the exemplary embodiment as described above, a detailed description thereof will be omitted in order to avoid an overlapping description. Here, first and second connection terminals having structures different from those in the exemplary embodiment described above will be described in detail with reference to FIGS. 7 and 8.

Referring to FIGS. 7 and 8, the first connection terminal may further include a third cut portion 145 formed in a portion connecting a first vertical portion 141 and a first upper horizontal portion 142 to each other, and the second connection terminal may further include a fourth cut portion 155 formed in a portion connecting a second vertical portion 151 and a second upper horizontal portion 152 to each other.

The third cut portion 145 may include a third stress suppression portion 145a formed on an upper end of the first vertical portion 141 and a third solder pocket 145b communicating with the third stress suppression portion 145a and formed in one end of the first upper horizontal portion 142.

The fourth cut portion 155 may include a fourth stress suppression portion 155a formed on an upper end of the second vertical portion 151 and a fourth solder pocket 155b communicating with the fourth stress suppression portion 155a and formed in one end of the second upper horizontal portion 152.

Here, the third cut portion 145 may be positioned in the center of the first connection terminal in a Y direction corresponding to a direction in which fifth and sixth surfaces 5 and 6 of the capacitor body 110 are connected to each other, and the fourth cut portion 155 may be positioned in the center of the second connection terminal in the Y direction corresponding to the direction in which the fifth and sixth surfaces 5 and 6 of the capacitor body 110 are connected to each other.

In a case of forming cut portions in upper and lower portions of the connection terminals to form a vertically symmetrical structure, at the time of adhering the connection terminals to the multilayer capacitor, directionality may be removed.

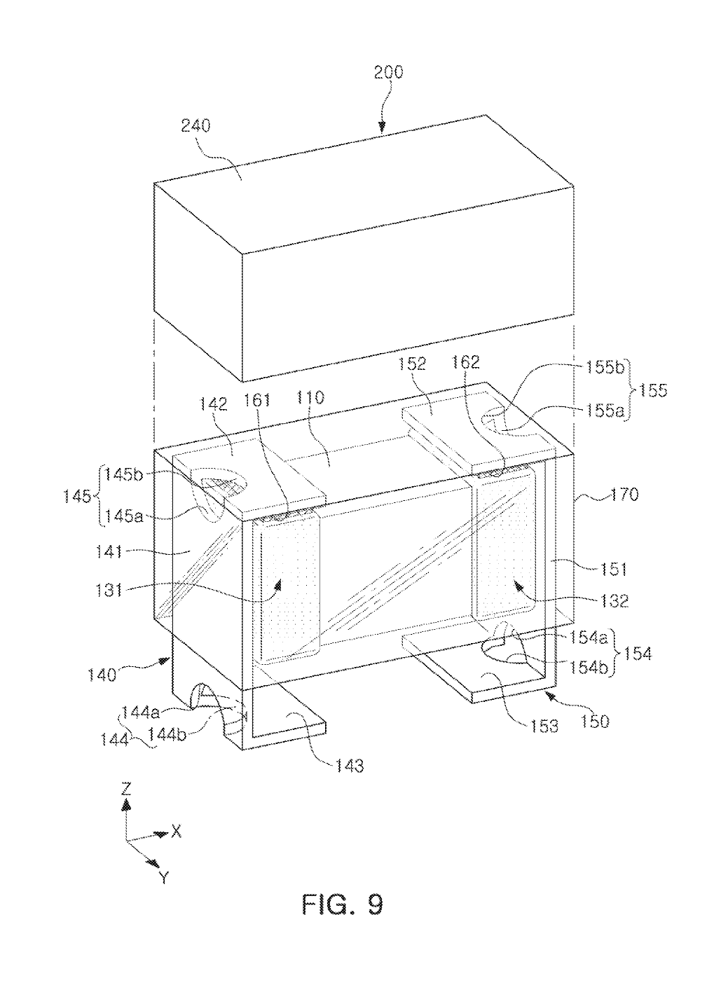

FIG. 9 is a transparent exploded perspective view of an electronic component according to a third exemplary embodiment in the present disclosure.

Since in the electronic component according to the third exemplary embodiment, structures of a capacitor body 110, first and second internal electrodes 121 and 122, and first and second external electrodes 131 and 132, and structures of a tantalum capacitor 200 are the same as those in the exemplary embodiment as described above, a detailed description thereof will be omitted in order to avoid an overlapping description. Here, a protection part having a structure different from that in the exemplary embodiment described above will be described in detail with reference to FIG. 9.

Referring to FIG. 9, the electronic component according to the present exemplary embodiment may further include a protection part 170.

The protection part 170 may be formed of an insulator, and formed to cover the capacitor body 110, the first and second external electrodes 131 and 132, and at least portions of upper portions of first and second connection terminals 140 and 150 in a state in which first and second cut portions 144 and 154 are exposed, and formed to expose first and second upper horizontal portions 142 and 152 of the first and second connection terminals 140 and 150.

Therefore, the first and second upper horizontal portions 142 and 152 may be connected to a cathode terminal portion and an anode terminal proton of the tantalum capacitor 200, respectively.

Here, as illustrated in FIG. 9, the protection part 170 may be formed to cover the capacitor body 110 and entire side surfaces of the first and second external electrodes 131 and 132.

When the protection part 170 is formed as described above, reliability of the multilayer capacitor 100 maybe improved. Particularly, stress suppression portions and solder pockets may be formed as they are in a direction of a mounting surface of the circuit board, such that an effect of deceasing acoustic noise may be maintained as it is, and reliability may be improved.

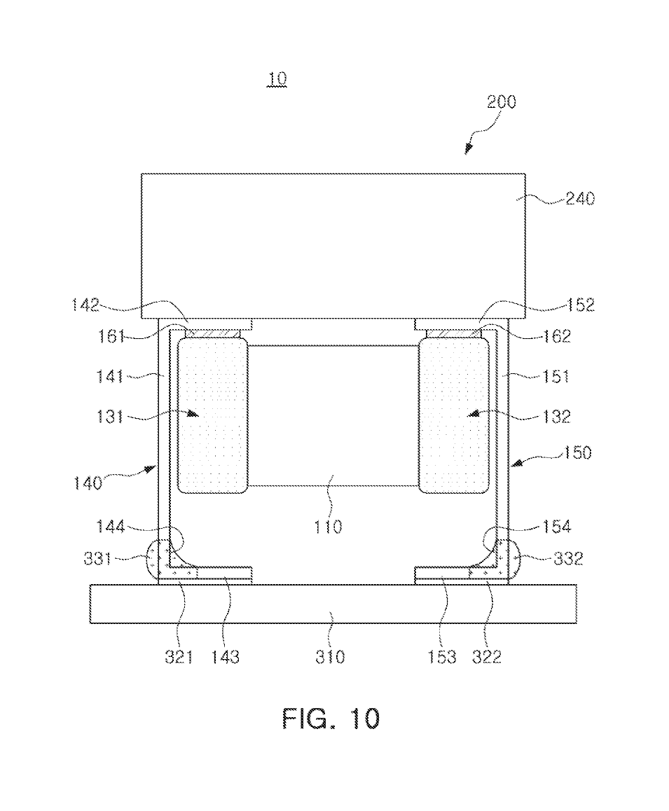

FIG. 10 is a front view schematically illustrating a board in which the electronic component according to the first exemplary embodiment in the present disclosure is mounted on a circuit board.

When voltages having different polarities are applied to the first and second external electrodes formed on the electronic component in a state in which the electronic component is mounted on the circuit board, the capacitor body may be expanded and contracted in the thickness direction by an inverse piezoelectric effect of the dielectric layer, and both end portions of the first and second external electrodes may be contracted and expanded as opposed to expansion and contraction of the capacitor body in the thickness direction by a Poisson effect.

The contraction and expansion as described above may generate vibration. In addition, the vibration may be transferred from the first and second external electrodes to the circuit board, and a sound is radiated from the circuit board, thereby generating acoustic noise.

Referring to FIG. 10, the board having an electronic component according to the present exemplary embodiment may include a circuit board 310 having one surface on which first and second electrode pads 321 and 322 are formed, and the electronic component mounted on an upper surface of the circuit board 310 so that the first and second connection terminals 140 and 150 are connected to the first and second electrode pads 321 and 322, respectively.

Here, although a case in which the electronic component 10 is mounted on the circuit board 310 by solders 331 and 332 is illustrated and described in the present exemplary embodiment, if necessary, a conductive paste may be used instead of the solder.

According to the present exemplary embodiment, the first and second cut portions 144 and 154 of the first and second connection terminals 140 and 150 may serve as solder packets capable of holding the solders 331 and 332 toward the first surface of the capacitor body 110.

Therefore, as the solders 331 and 332 are effectively held in the first and second solder pockets 144 and 154 at the time of mounting the electronic component 10 on the circuit board 310, formation of solder fillet on the capacitor body 110 and the first and second external electrodes 131 and 132 may be suppressed.

Therefore, a path through which the piezoelectric vibration of the electronic component 10 is transferred may be blocked, and the solder fillet and a maximum displacement point in the capacitor body 110 may be spaced apart from each other, such that the effect of decreasing acoustic noise of the electronic component 10 may be improved.

Further, according to the present exemplary embodiment, a vibration amount of the piezoelectric vibration of the electronic component transferred to the circuit board in an audio frequency of 20 kHz or less in the electronic component may be effectively suppressed by the above-mentioned structure in which acoustic noise is decreased.

Therefore, high-frequency vibrations of the electronic component may be decreased, such that problems such as malfunction of sensors caused by the high-frequency vibrations of the electronic component at 20 kHz or more in information technology (IT) or industrial/electronic fields may be prevented, and internal fatigue accumulation of the sensors by the vibration for a long period of time may be suppressed.

According to the present exemplary embodiment, excellent ESL and ESR characteristics of the multilayer capacitor in addition to high capacitance of the tantalum capacitor may be secured, and the effect of decreasing acoustic noise and the effect of improving reliability may be further secured by using the connection terminals.

When a tantalum capacitor is directly adhered on external electrodes of a multilayer capacitor, in a case in which adhesion positions are misaligned, capacitance may be decreased, or an effect of decreasing acoustic noise may be decreased.

However, according to the present exemplary embodiment, it may be easy to set a position of the tantalum capacitor by adhering the lower surfaces of the connection terminals to the band portions on upper portions of the multilayer capacitor, and adhering the tantalum capacitor to the upper surfaces of these connection terminals, such that a decrease in capacitance may be prevented, and deterioration of the effect of decreasing acoustic noise may be prevented.

Further, according to the present exemplary embodiment, since the tantalum capacitor is disposed in an upper portion of the electronic component and the upper surface of the tantalum capacitor is flat, at the time of coming in contact with a surface mount device (SMD) nozzle, an adsorption defect may be prevented.

As set forth above, according to exemplary embodiments in the present disclosure, a composite component may be formed so that the multilayer capacitor is disposed to be close to the mounting surface and the tantalum capacitor is disposed to be far away from the mounting surface based on the connection terminal, such that the electronic component of which electrical properties and reliability are improved and in which acoustic noise in an audio frequency region of 20 kHz or less and high-frequency vibrations of 20 kHz or more are decreased may be provided.

While exemplary embodiments have been shown and described above, it will be apparent to those skilled in the art that modifications and variations could be made without departing from the scope of the present invention as defined by the appended claims.

What is claimed is:

1. An electronic component comprising:
a capacitor body including a plurality of dielectric layers and a plurality of first and second internal electrodes alternately disposed with respective dielectric layers interposed therebetween and having first and second surfaces opposing each other, third and fourth surfaces connected to the first and second surfaces and opposing each other, and fifth and sixth surfaces connected to the first and second surfaces and the third and fourth surfaces and opposing each other, one ends of the first and second internal electrodes being exposed to the third and fourth surfaces of the capacitor body;
first and second external electrodes disposed on the third and fourth surfaces of the capacitor body, respectively; and
first and second connection terminals connected to the first and second external electrodes, respectively,
wherein the first connection terminal includes: a first vertical portion disposed to face the first external electrode; a first lower horizontal portion extending from a lower end of the first vertical portion in a direction toward the fourth surface of the capacitor body; a first upper horizontal portion extending from an upper end of the first vertical portion in the direction toward the fourth surface of the capacitor body; and a first cut portion formed in a portion connecting the first vertical portion and the first lower horizontal portion,
the second connection terminal includes: a second vertical portion disposed to face the second external electrode; a second lower horizontal portion extending from a lower end of the second vertical portion in a direction toward the third surface of the capacitor body; a second upper horizontal portion extending from an upper end of the second vertical portion in the direction toward the third surface of the capacitor body; and a second cut portion formed in a portion connecting the second vertical portion and the second lower horizontal portion, and
the electronic component further comprises a tantalum capacitor having an anode and a cathode connected to the second and first upper horizontal portions, respectively.

2. The electronic component of claim 1, wherein the first and second upper horizontal portions are adhered to the first and second external electrodes, respectively,
the first vertical portion and the first lower horizontal portion are disposed to be spaced apart from the first external electrode, and
the second vertical portion and the second lower horizontal portion are disposed to be spaced apart from the second external electrode.

3. The electronic component of claim 1, wherein the first and second lower horizontal portions are mounting portions.

4. The electronic component of claim 1, wherein the first cut portion includes: a first stress suppression portion formed in the lower end of the first vertical portion; and a first solder pocket communicating with the first stress suppression portion and formed in one end of the first lower horizontal portion, and
the second cut portion includes: a second stress suppression portion formed in the lower end of the second vertical portion; and a second solder pocket communicating with the second stress suppression portion and formed in one end of the second lower horizontal portion.

5. The electronic component of claim 1, wherein the first cut portion is positioned in a center of the first connection terminal in a direction in which the fifth and sixth surfaces of the capacitor body are connected to each other, and
the second cut portion is positioned in a center of the second connection terminal in the direction in which the fifth and sixth surfaces of the capacitor body are connected to each other.

6. The electronic component of claim 1, further comprising conductive adhesive layers disposed between the first external electrode and the first upper horizontal portion and between the second external electrode and the second upper horizontal portion, respectively.

7. The electronic component of claim 1, wherein the first and second external electrodes respectively include first and second body portions disposed on the third and fourth surfaces of the capacitor body, respectively; and first and second band portions extending from the first and second body portions to portions of the second surface of the capacitor body, respectively,
the first and second vertical portions are disposed to be spaced apart from the first and second body portions, respectively, and
the first and second upper horizontal portions are connected to the first and second band portions, respectively.

8. The electronic component of claim 7, wherein the first connection terminal further includes a third cut portion formed in a portion connecting the first vertical portion and the first upper horizontal portion, and
the second connection terminal further includes a fourth cut portion formed in a portion connecting the second vertical portion and the second upper horizontal portion.

9. The electronic component of claim 8, wherein the third cut portion includes: a third stress suppression portion formed in the upper end of the first vertical portion; and a third solder pocket communicating with the third stress suppression portion and formed in one end of the first upper horizontal portion, and
the fourth cut portion includes: a fourth stress suppression portion formed in the upper end of the second vertical portion; and a fourth solder pocket communicating with the fourth stress suppression portion and formed in one end of the second upper horizontal portion.

10. The electronic component of claim 8, wherein the third cut portion is positioned in a center of the first connection terminal in a direction in which the fifth and sixth surfaces of the capacitor body are connected to each other, and
the fourth cut portion is positioned in a center of the second connection terminal in the direction in which the fifth and sixth surfaces of the capacitor body are connected to each other.

11. The electronic component of claim 1, further comprising a protection part formed of an insulator, and covering the capacitor body, the first and second external electrodes, and at least portions of upper portions of first and second connection terminals in a state in which the first and second cut portions are exposed, and exposing the first and second upper horizontal portions of the first and second connection terminals.

12. The electronic component of claim 1, wherein the tantalum capacitor includes:
a tantalum body;
a tantalum wire exposed to one surface of the tantalum body;
an anode terminal connected to the tantalum wire;
a cathode terminal on which the tantalum body is mounted; and
a cover part covering the tantalum body and the tantalum wire and exposing a lower surface of the anode terminal and a lower surface of the cathode terminal.

13. An electronic component comprising:
a multilayer capacitor having both ends on which external electrodes are disposed;
connection terminals including vertical portions, lower horizontal portions having cut portions, respectively, and upper horizontal portions, respectively, lower surfaces of the upper horizontal portions being connected to the external electrodes; and
a tantalum capacitor disposed on upper surfaces of the upper horizontal portions to be electrically connected thereto.

14. A board having an electronic component, the board comprising:
a circuit board having one surface on which first and second electrode pads are formed; and
the electronic component of claim 13, mounted on the first and second electrode pads,
wherein the first and second lower horizontal portions of the first and second connection terminals are connected to the first and second electrode pads, respectively.

15. A board having an electronic component, the board comprising:
a circuit board having one surface on which first and second electrode pads are formed; and
the electronic component of claim 1, mounted on the first and second electrode pads,
wherein the first and second lower horizontal portions of the first and second connection terminals are connected to the first and second electrode pads, respectively.
